(19) United States
(12) Patent Application Publication
(10) Pub. No.: US 2020/0196435 A1
(43) Pub. Date: Jun. 18, 2020

(54) METHOD OF MANUFACTURING MULTI-STRUCTURAL HIGH-HEAT-DISSIPATION PART HAVING CONTROLLED PACKING DENSITY OF CARBON MATERIAL, AND MULTI-STRUCTURAL HIGH-HEAT-DISSIPATION PART MANUFACTURED THEREBY

(71) Applicant: MORGAN CO., LTD., Daegu (KR)

(72) Inventors: Jong Seok Woo, Daegu (KR); Mun Hee Lee, Daegu (KR); Byung Choon Kim, Daegu (KR); Kwang Sang Park, Daegu (KR); Sung Hoon Park, Seoul (KR)

(73) Assignee: MORGAN CO., LTD.

(21) Appl. No.: 16/581,913

(22) Filed: Sep. 25, 2019

(30) Foreign Application Priority Data
Dec. 18, 2018 (KR) 10-2018-0164283

(51) Int. Cl. H05K 1/02; C01B 32/05

(52) U.S. Cl. CPC H05K 1/0204; C08L 95/00; C01B 32/05

(57) ABSTRACT

The present invention relates to a method of manufacturing a multi-structural high-heat-dissipation part having the controlled packing density of a carbon material and to a multi-structural high-heat-dissipation part manufactured thereby, the method including preparing a mixture by mixing a binder pitch with a carbon material including a first carbon material powder and a second carbon material powder having a smaller diameter than the diameter of the first carbon material powder, forming a compact from the mixture using a hot-forming process, and producing a graphitized pitch/carbon material compact by subjecting the compact to graphitization through heat treatment and cooling. Thereby, the packing density of the carbon material can be improved through bimodal distribution using pieces of carbon material having different diameters, thus increasing thermal conductivity in in-plane and through-plane directions and strength.

### REFERENCE TO RELATED APPLICATIONS

This application claims the priority benefit of Korean Patent Application No. 10-2018-0164283 filed on Dec. 18, 2018, the entire contents of which are incorporated herein by reference.

### FIELD OF THE INVENTION

The present invention relates to a method of manufacturing a multi-structural high-heat-dissipation part having the controlled packing density of a carbon material and a multi-structural high-heat-dissipation part manufactured thereby, and more particularly to a method of manufacturing a multi-structural high-heat-dissipation part having improved packing density and superior thermal conductivity by manufacturing a heat-dissipation part material using a binder pitch and pieces of carbon material having different diameters, and a multi-structural high-heat-dissipation part manufactured thereby.

### BACKGROUND OF THE INVENTION

Recently, electronic devices for use in automotive, electrical, and electronic fields have been developed to be lighter, thinner, smaller, and more versatile. As these electronic devices become more integrated, more heat is generated therefrom. Since the heat thus generated not only degrades the function of the device, but also causes malfunctions in peripheral devices, substrate degradation, and the like, technologies for controlling the generated heat are receiving a great deal of attention, and research thereon is actively being conducted.

In particular, a high-heat-dissipation circuit board material is capable of utilizing the thermal conductivity of a base metal substrate, which is advantageous for the fabrication of high-power-consuming and heat-generating parts such as power devices and LED modules. Interest in research and development thereon is increasing.

Typically, a heat-dissipation sheet such as a heat-dissipation rubber or a gel sheet is used to efficiently transfer heat to a heat sink or the like, and development thereof is underway. However, in the case of such a heat-dissipation sheet, there are problems such as poor contact due to the adhesion of an insulator produced by low-molecular-weight siloxane. Therefore, it is necessary to develop high-heat-dissipation parts for use in electric vehicles and parts.

In this regard, Korean Patent No. 10-1509494 discloses a heat-dissipation sheet for electronic devices using graphite, in which the graphite layer includes natural graphite or artificial graphite. However, manufacture of the sheet using only one size of graphite in this way is problematic because the packing density is lowered due to voids and thus the thermal conductivity is decreased.

Also, Korean Patent No. 10-1618736 discloses an isotropic graphite compact and a method of producing the same, the method including subjecting graphite and a binder pitch to mixing, forming and graphitization. In the case of such a pitch/coke-based isotropic graphite compact, the in-plane and through-plane thermal conductivities are different, but are lowered due to the orientation and crystallinity of graphite.

Therefore, methods for solving the above problems are required.

### SUMMARY OF THE INVENTION

Accordingly, the present invention has been made keeping in mind the problems encountered in the related art, and an objective of the present invention is to provide a method of manufacturing a multi-structural high-heat-dissipation part having improved packing density and superior thermal conductivity by manufacturing a heat-dissipation part using a binder pitch and pieces of carbon material having different diameters, and a multi-structural high-heat-dissipation part manufactured thereby.

The objectives of the present invention are not limited to the foregoing, and other objectives not mentioned herein will be able to be clearly understood by those skilled in the art from the following description.

In order to accomplish the above objective, the present invention provides a method of manufacturing a multi-structural high-heat-dissipation part having the controlled packing density of a carbon material, the method including preparing a mixture by mixing a binder pitch with a carbon material including a first carbon material powder and a second carbon material powder having a smaller size than the size of the first carbon material powder, forming a compact from the mixture using a hot-forming process, and producing a graphitized binder pitch/carbon material compact by subjecting the compact to graphitization through heat treatment and cooling.

Here, the first carbon material powder may have a diameter of 400 to 500 μm and the second carbon material powder may have a diameter of 10 to 100 μm.

The carbon material may include, based on 100 wt % thereof, 50 to 90 wt % of the first carbon material powder and 10 to 50 wt % of the second carbon material powder. The carbon material may be selected from the group consisting of graphite, carbon black, carbon nanotubes, carbon fiber, graphene and combinations thereof.

Also, the binder pitch may have a softening point of 100° C. to 200° C., and the binder pitch may have a particle size of 1 to 100 μm.

The mixture may include, based on 100 wt % thereof, 10 to 20 wt % of the binder pitch and 80 to 90 wt % of the carbon material.

The hot-forming process may be performed at a temperature ranging from 200° C. to 400° C. The binder pitch/carbon material compact may have a density of 1.7 to 2.2 g/cm³.

In addition, the present invention provides a multi-structural high-heat-dissipation part having the controlled packing density of a carbon material, the multi-structural high-heat-dissipation part including a binder pitch and a carbon material including a first carbon material powder and a second carbon material powder having a smaller size than the size of the first carbon material powder, in which the binder pitch and the carbon material are mixed, hot-formed, and graphitized, thus producing a binder pitch/carbon material compact.

According to the present invention, the packing density of a carbon material can be improved through bimodal distribution using pieces of carbon material having different diameters, thereby increasing thermal conductivity and strength. Moreover, it is easy to manufacture a multi-structural high-heat-dissipation part having excellent thermal conductivity in in-plane and through-plane directions by controlling the structure of graphite in the compact depending on changes in the diameter of the carbon material.

The effects of the present invention are not limited to the foregoing, and other effects not mentioned herein will be able to be clearly understood by those skilled in the art from the description of the claims.

### BRIEF DESCRIPTION OF THE DRAWINGS

FIG. 1 is a flowchart showing a process of manufacturing a multi-structural high-heat-dissipation part having the controlled packing density of a carbon material according to an embodiment of the present invention;

FIG. 2 is an optimal microscope image of a multi-structural high-heat-dissipation part having the controlled packing density of a carbon material according to an embodiment of the present invention;

FIGS. 3A and 3B are optimal microscope images of binder pitch/carbon material compacts in Test Examples 1 and 2;

FIG. 4 is a graph showing the thermal decomposition temperature depending on the softening point of a binder pitch;

FIGS. 5A to 5C are optimal microscope images of the binder pitch/carbon material compact depending on the hot-forming temperature in a hot-forming process;

FIG. 6 is a photograph showing a binder pitch/carbon material compact product according to an embodiment of the present invention; and

FIG. 7 is an optimal microscope image of the binder pitch/carbon material compact produced using a cold-press forming machine in Comparative Example 1.

### DETAILED DESCRIPTION OF THE INVENTION

Hereinafter, a detailed description will be given of a method of manufacturing a multi-structural high-heat-dissipation part having the controlled packing density of a carbon material and a multi-structural high-heat-dissipation part manufactured thereby according to embodiments of the present invention, with reference to the accompanying drawings.

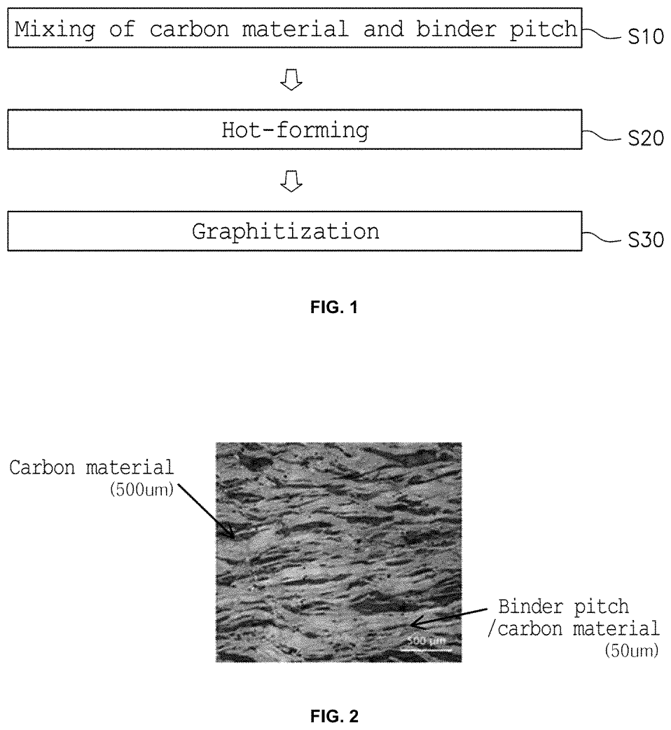

As shown in FIG. 1, the method of manufacturing a multi-structural high-heat-dissipation part having the controlled packing density of a carbon material according to the present invention may include subjecting a carbon material and a binder pitch to mixing (S10), hot-forming (S20) and graphitization (S30).

Specifically, a carbon material and a binder pitch are mixed to afford a mixture (S10).

The carbon material may be selected from the group consisting of graphite, carbon black, carbon nanotubes, carbon fiber, graphene and combinations thereof, but the present invention is not limited thereto.

Here, the carbon material may include a first carbon material powder and a second carbon material powder having a smaller size than the size of the first carbon material powder. Particularly, the first carbon material powder may have a diameter of 400 to 500 μm and the second carbon material powder may have a diameter of 10 to 100 μm.

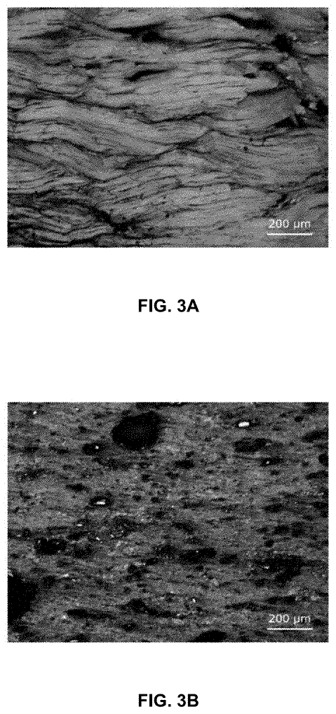

With reference to FIG. 3A, when the carbon material having a relatively large size is used alone, it is efficiently arranged in an in-plane direction to which pressure is applied, whereby in-plane thermal conductivity is high but strength is lowered, which is undesirable. Specifically, when natural graphite having a large size is formed using a hot-forming machine, it is arranged in an in-plane direction and thus in-plane thermal conductivity is high but structural strength is undesirably decreased. Moreover, graphite having a large diameter is able to very strongly bind to the binder pitch having a small diameter because of interfacial interaction, and thus there is no aggregated pitch.

With reference to FIG. 3B, when the carbon material having a small diameter is used alone, it is oriented in random directions, and thus strength is enhanced but the binder pitch does not wrap the carbon material having a relatively small diameter and therefore an aggregated binder pitch is created, which is undesirable. Specifically, since graphite having a small diameter is oriented in random directions, strength is enhanced but the binder pitch does not wrap small graphite, undesirably creating the aggregated binder pitch.

Also, graphite having a small diameter has superior crystallinity but is nonuniform in thermal conductivity due to the small particle size thereof, and thus, thermal conductivity is decreased compared to graphite having a relatively large diameter, but the movement path is increased upon measurement of flexural strength due to the structural effect of graphite by virtue of the small particle size, thereby exhibiting higher strength than in the case of large particles.

Accordingly, when the binder pitch is mixed with the carbon material including the first carbon material powder and the second carbon material powder, having a smaller diameter than that of the first carbon material powder, as shown in FIG. 2, the second carbon material powder is positioned between particles of the first carbon material powder, thus minimizing voids, thereby improving mechanical and thermal properties.

Under the assumption that the density and thickness of the first carbon material powder and the second carbon material powder are the same and the particles thereof are spherical, the minimum void ratio may be calculated using Equation 1 below.

$${P}_{R} = \frac{{W}_{R}}{π \times {R}^{2} \times {t}^{′}} = {ρ}_{r} = \frac{{W}_{r}}{π \times {r}^{2} \times t} \qquad [ Equation 1 ]$$

Here, R is the radius of the first carbon material powder, W_{R} is the weight of the first carbon material powder, and P_{R} is the density of the first carbon material powder. Furthermore, r is the radius of the second carbon material powder, Wᵣ is the weight of the second carbon material powder, and ρᵣ is the density of the second carbon material powder.

For example, assuming that the first carbon material powder has a diameter of 500 μm and the second carbon material powder has a diameter of 50 μm, the ratio W_{R}:Wᵣ, at which the voids may be minimized, is calculated to be 78.5:21.5.

Thus, the carbon material may include, based on 100 wt % thereof, 50 to 90 wt % of the first carbon material powder and 10 to 50 wt % of the second carbon material powder, and particularly, about 80 wt % of the first carbon material powder and 20 wt % of the second carbon material powder.

In general, the term “binder pitch” refers to a pitch that is added during kneading or mixing, and examples thereof may include coal-based and petroleum-based pitches, but the binder pitch according to the present invention may be a coal-based pitch.

In the mixing step, the binder pitch and the carbon material are mixed at a predetermined temperature for a predetermined time. Here, the predetermined temperature may be set to be higher than the softening point of the binder pitch.

Here, the softening point of the binder pitch may fall in the range of 100° C. to 200° C. If the softening point thereof is lower than 100° C., swelling and cracking may be caused by highly volatile gases. On the other hand, if the softening point thereof is higher than 200° C., the binder pitch cannot function as a binder owing to the high viscosity. Hence, the softening point of the binder pitch may be set within the above temperature range, and superior formability may result due to proper viscosity.

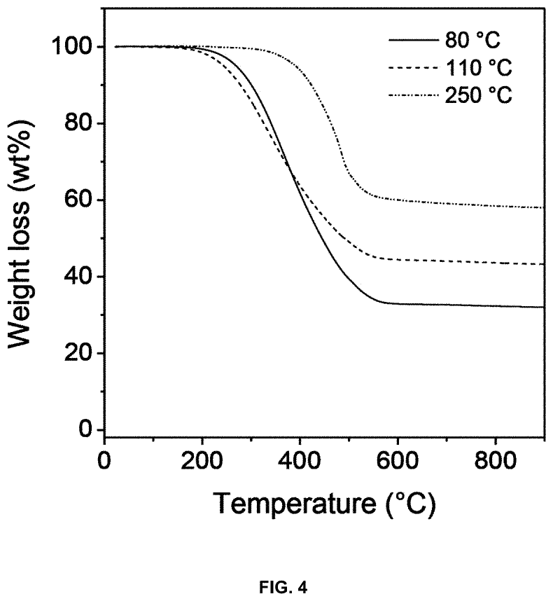

With reference to FIG. 4, based on the results of TGA (thermogravimetric analysis) among binder pitches having different softening points, weight loss occurs at a temperature equal to or higher than the softening point. The higher the softening point, the higher the char yield.

Meanwhile, the particle size of the binder pitch may be 1 to 100 μm. If the particle size thereof is less than 1 it is difficult to form binder pitch particles. On the other hand, if the particle size thereof exceeds 100 μm, it is difficult to uniformly mix with the carbon material powder.

Subsequently, the mixture is formed into a compact through a hot-forming process (S20).

The binder pitch is volatilized during heat treatment in the subsequent graphitization step, and weight loss occurs, resulting in decreased density and increased porosity. Hence, in order to manufacture a compact having high density, the hot-forming process may be performed.

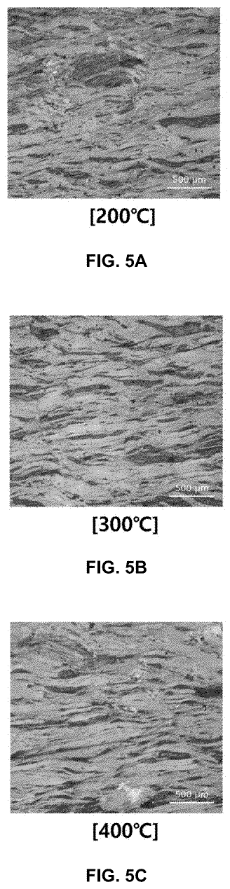

As shown in FIGS. 5A to 5C, the density may be increased at a hot-forming temperature of 300° C., rather than 200° C., and when the hot-forming temperature is 400° C., a density similar to the case of 300 □ C may result. Also, the lower the hot-forming temperature, the more the binder pitch is aggregated. A uniform microstructure may be obtained because the viscosity of the pitch is lowered with an increase in the temperature. Hence, the hot-forming process may be carried out at a temperature ranging from 200° C. to 400° C.

Finally, the compact is subjected to graphitization through heat treatment and cooling, thus producing a graphitized binder pitch/carbon material compact (S30).

Here, the graphitized binder pitch/carbon material compact may be formed so as to have a density of 1.7 to 2.2 g/cm³. Through the following examples, it can be confirmed that when using the binder pitch and the pieces of carbon material having different diameters, the packing density may be improved compared to when using the carbon material having the consistent diameter.

A better understanding of the present invention will be given through the following examples.

### Test Example 1

A carbon material may be selected from the group consisting of graphite, carbon black, carbon nanotubes, carbon fiber, graphene and combinations thereof. In this test Example, as the carbon material, natural graphite having a consistent particle size of 500 μm was used.

A coal-based binder pitch (Handan Jinghao Chemical Co., Ltd, softening point of 110° C.) and natural graphite (Asbury, #3763) depending on the binder pitch content were weighed, mixed using a kneader One Shokai Co. Ltd., PNV-1H) at 160° C. for 1 hr, and maintained at 300° C. under a pressure of 20 MPa for 30 min using a hot-forming machine (Ilshin Autoclave, HT-15T) and thus formed into a sample having a size of 30×30×15 mm.

Subsequently, the compact thus obtained was placed in a crucible and then heat-treated to 2500° C. in a graphitization furnace (ThermoNik, RD-15G). During the heat treatment, the temperature was elevated to 1000° C. from room temperature at a rate of 0.5° C./min, and then elevated to 1000-2500° C. at a rate of 5° C./min. The compact was maintained at 2500° C. for 1 hr and then naturally cooled.

The density and thermal conductivity of the graphitized sample were measured. The density was determined in a manner in which dried weight W₁, saturated weight W₂, and submerged weight W₃ were measured using an Archimedes method and then substituted into Equation 2 below.

$$\text{density} = \frac{{W}_{1}}{{W}_{2} - {W}_{3}} \qquad [ Equation 2 ]$$

For measurement of thermal conductivity, the heat-treated sample was processed to 10×10×2 mm and then evaluated using a thermal conductivity meter (Netzsch, LFA 457) through a laser flash method. Thermal conductivity is determined by applying a laser pulse to the sample, observing the temperature signal over time, measuring the thermal diffusivity inside the sample, and calculating the thermal conductivity using the following equation.

Thermal conductivity (W/mk)=density (g/cm³)×specific heat (j/g/k)×thermal diffusivity (mm²/s) [Equation 3]

Based on the measurement results, it was confirmed that the 500 μm natural graphite/pitch compact had high crystallinity and orientation and thus exhibited high thermal conductivity in the x and y directions but low thermal conductivity in the z-axis direction.

The changes in the density of the 500 μm natural graphite/pitch compact depending on the binder pitch content are shown in Table 1 below. As the binder pitch content increased, the binder pitch was removed after heat treatment, thus increasing porosity and decreasing density.

TABLE 1

| Pitch content (wt %) | 5 | 10 | 15 | 20 |
|---|---|---|---|---|
| Density (g cm⁻³) | 2.07 | 1.99 | 1.78 | 1.58 |
| Density after heat treatment | 1.75 | 1.65 | 1.48 | 1.21 |
| Porosity (%) | 15.4 | 19.5 | 23.5 | 32.8 |

### Test Example 2

A carbon material may be selected from the group consisting of graphite, carbon black, carbon nanotubes, carbon fiber, graphene and combinations thereof. In this test Example, as the carbon material, natural graphite having a consistent particle size of 50 was used.

This test example was performed in the same manner as in Test Example 1, with the exception that natural graphite (50 μm, Asbury, #3464) was used. Graphite having a relatively small diameter has superior crystallinity but is nonuniform in thermal conductivity due to the small particle size thereof, and thus, thermal conductivity is decreased compared to relatively large graphite. However, the movement path is increased upon application of a load during measurement of flexural strength due to the structural effect of graphite by virtue of the small particle size, thereby exhibiting higher strength than in the case of large particles.

The changes in the density of the 50 μm natural graphite/pitch compact depending on the binder pitch content are shown in Table 2 below.

TABLE 2

| Pitch content (wt %) | 5 | 10 | 15 | 20 |
|---|---|---|---|---|
| Density (g cm⁻³) | 1.94 | 1.87 | 1.67 | 1.49 |
| Density after heat | 1.57 | 1.48 | 1.39 | 1.18 |
| treatment | | | | |
| Porosity (%) | 20.9 | 24.2 | 29.6 | 36.8 |

FIGS. 3A and 3B are optimal microscope (Epiphot 200, Nikon) images showing the microstructures of the samples manufactured in Test Examples 1 and 2.

FIG. 3A is an image showing the 500 μm natural graphite/pitch compact, and FIG. 3B is an image showing the 50 μm natural graphite/pitch compact.

When using the 500 μm natural graphite, it is efficiently arranged in an in-plane direction to which pressure is applied and thus in-plane thermal conductivity is superior but strength is undesirably lowered. Specifically, when natural graphite having a large size is formed using a hot-forming machine, in-plane thermal conductivity is superior due to in-plane arrangement, but structural strength is lowered, which is undesirable. Also, graphite having a large diameter exhibits superior interfacial interaction with the binder pitch, and thus there is no aggregated pitch.

On the other hand, when using the 50 μm natural graphite, it is oriented in random directions, and thus strength is enhanced, but the binder pitch does not wrap the carbon material having a relatively small diameter, and thus an aggregated binder pitch is created.

### Test Example 3

This test example was performed in the same manner as in Test Example 1, with the exception that binder pitches having softening points of 80, 110 and 250° C. and 500 μm natural graphite were used. Here, a mixing process was carried out using a kneader at a temperature higher than the softening point.

Based on the test results, in the case of the binder pitch having a softening point of 80° C., swelling and cracking occurred due to highly volatile gases, and the binder pitch, having a softening point of 250° C., did not play a role as a binder due to the high viscosity thereof.

The binder pitch having a softening point of 110° C. exhibited superior formability due to proper viscosity.

Meanwhile, during the graphitization after the hot-forming process, the volatilization point of the binder pitch is regarded as important. Here, the volatilization point of the binder pitch may be set within the range of 110 to 150° C.

With reference to FIG. 4, based on the results of TGA (Shinko, N1000) among binder pitches having different softening points, the binder pitch having a softening point of 80° C. initiated weight loss from 200° C., the binder pitch having a softening point of 110° C. initiated weight loss from 250° C., and the binder pitch having a softening point of 250° C. caused weight loss from 350° C. to 500° C. Also, the higher the softening point, the higher the char yield. Specifically, weight loss occurred at a temperature equal to or higher than the softening point, and the char yield was increased with an increase in the softening point.

TABLE 3

| | Softening | Carbon | | | | | |
|---|---|---|---|---|---|---|---|
| Binder | point | yield | Elemental analysis (%) | | | | |
| pitch | (° C.) | (wt %) | C | H | N | S | N + S |
| 1 | 75-90 | 32.30 | 91.97 | 4.29 | 0.95 | 0.50 | 1.45 |
| 2 | 108-112 | 43.59 | 91.65 | 4.40 | 0.98 | 0.51 | 1.40 |
| 3 | 250-255 | 58.43 | 92.95 | 5.21 | 0.06 | 0.01 | 0.07 |

Table 3 shows the elemental analysis results of the binder pitch depending on the softening point. Based on the elemental analysis results of the binder pitch, the amounts of C were measured to be 91.97, 91.65, and 95.95%. Also, S and N of the binder pitch were observed to interfere with crystallinity in the graphitization step, and the binder pitch that was used had an impurity content of about 1.5%. As is apparent from Table 3, the binder pitch having a softening point of 250 to 255° C. had very low content of N and S. Thus, the binder pitch having a high softening point exhibited high crystallinity based on the elemental analysis results thereof, but the resulting compact cracked. Hence, the softening point of the binder pitch may be set within the range of 100° C. to 200° C.

### Test Example 4

During the heat treatment of the binder pitch/carbon material compact, the binder pitch is volatilized and weight loss occurs, and thus low density and high porosity may result. Hence, it is necessary to produce a compact having high density. To this end, a hot-forming process was performed at 150, 200, 300 and 400° C.

The binder pitch having a softening point of 110° C. was used, and the temperature was elevated to the softening point of the binder pitch, that is, 110° C., at a rate of 10° C./min, and then elevated at a rate of 3° C./min.

The hot-forming temperature was elevated to each of 150, 200, 300, and 400° C., and then maintained for 30 min, thereby manufacturing samples.

Table 4 below shows changes in the density depending on the hot-forming temperature.

TABLE 4

| Hot-forming temperature (° C.) | 150 | 200 | 300 | 400 |
|---|---|---|---|---|
| Density (g cm⁻³) | 1.98 | 1.99 | 2.00 | 2.00 |

As is apparent from Table 4, the higher the hot-forming temperature, the higher the density. There was no change in the density at a temperature of 300° C. or higher.

With reference to FIGS. 5A to 5C, the lower the hot-forming temperature, the more the binder pitch was aggregated. Moreover, as the temperature was higher, the viscosity of the binder pitch was decreased, resulting in a uniform microstructure.

### Test Example 5

A commercially available isotropic compact was tested.

The thermal conductivity of a commercially available isotropic graphite compact (Nippon coke, GS-203R) was measured for comparison with the invented binder pitch/natural graphite. The isotropic graphite had a low thermal conductivity of 23 W/mK owing to differences in particle size and orientation compared to the invented graphite compact, but the in-plane and through-plane thermal conductivities of the isotropic graphite were similar. Moreover, the strength was 59 MPa due to the structural effect, and low thermal conductivity resulted.

### EXAMPLE

In Example according to the present invention, a binder pitch having a softening point of 110° C., and, as a carbon material, pieces of natural graphite having different diameters of 500 μm and 50 μm were prepared. A sample was manufactured in the same manner as in Test Example above.

Under the assumption that upon packing of 500 μm and 50 μm natural graphite, the density and thickness of the natural graphite are the same and the particles thereof are spherical, the minimum void ratio may be calculated using Equation 1 below.

$${P}_{R} = \frac{{W}_{R}}{π \times {R}^{2} \times {t}^{′}} = {ρ}_{r} = \frac{{W}_{r}}{π \times {r}^{2} \times t} \qquad [ Equation 1 ]$$

Here, W_{R} is the weight of 500 μm natural graphite, Wᵣ is the weight of 50 μm natural graphite, R is the radius of 500 μm natural graphite, r is the radius of 50 μm natural graphite, P_{R} is the density of 500 μm natural graphite, and ρᵣ is the density of 50 μm natural graphite.

Through the modeling described above, it can be confirmed that the voids are minimized when the amounts of 500 natural graphite and natural graphite are 78.5 wt % and 21.5 wt %, respectively.

Thus, the carbon material may include, based on 100 wt % thereof, 50 to 90 wt % of the first carbon material powder and 10 to 50 wt % of the second carbon material powder, and particularly, 78.5 wt % of the first carbon material powder and 21.5 wt % of the second carbon material powder.

Therefore, the second carbon material powder having a relatively small diameter is positioned between particles of the first carbon material powder having a large diameter, thereby minimizing voids, ultimately improving the mechanical and thermal properties of the heat-dissipation part.

TABLE 5

| Pitch content (wt %) | 5 | 10 | 15 | 20 |
|---|---|---|---|---|
| Density of compact (g cm⁻³) | 2.13 | 2.05 | 1.94 | 1.81 |
| Density after heat treatment (g cm⁻³) | 1.87 | 1.74 | 1.57 | 1.42 |
| Porosity (%) | 10.8 | 16.5 | 23.53 | 25.9 |

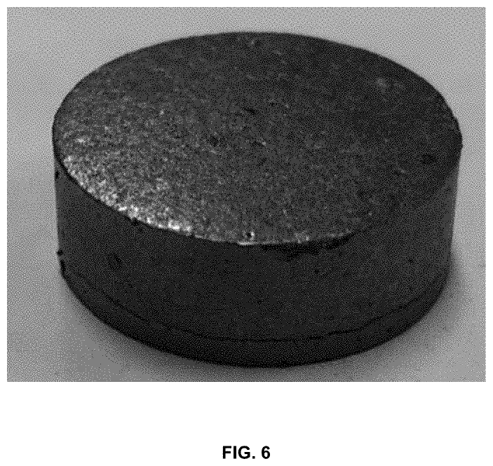

Table 5 shows changes in density and porosity depending on the binder pitch content in the binder pitch/carbon material compact of Example according to the present invention. When the binder pitch/carbon material compact was manufactured using 100 wt % of the binder pitch and pieces of natural graphite having different diameters of 50 μm and 500 μm, the density of the compact was 20.5 g/cm3 and the density after heat treatment was 1.74 g/cm3. The product manufactured by the method of the present invention is illustrated in FIG. 6.

With reference to Table 1 of Test Example 1, in the sample using natural graphite having a diameter of 500 the density after heat treatment was 1.65 g/cm³, and with reference to Table 2 of Test Example 2, in the sample using natural graphite having a diameter of 50 the density after heat treatment was 1.48 g/cm³.

Therefore, compared to when the compact was manufactured using the carbon material having the consistent diameter, when the binder pitch/carbon material compact was manufactured using the pieces of carbon material having different diameters according to the present invention, higher density resulted.

### Comparative Example 1

In Comparative Example 1, cold forming, in which a temperature was not applied, was performed.

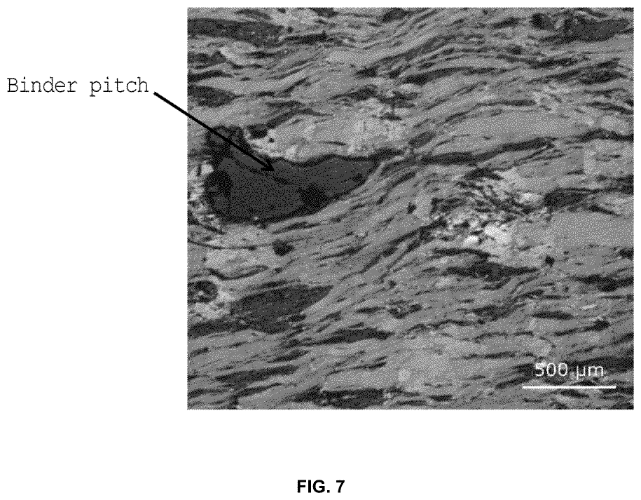

The same natural graphite composition as in Example was used, and the mixing process was carried out using a kneader at the same temperature for the same amount of time. The mixed powder was formed under the same conditions at room temperature using a hot-forming machine (Ilshin Autoclave, HT-15T). The sample thus formed had a density of 1.925 g/cm³, which is lower than that in the hot-forming process. As shown in FIG. 7, the binder pitch was aggregated in the undissolved portion when forming at room temperature, which causes the thermal and mechanical properties of the heat-dissipation part to deteriorate.

### Comparative Example 2

The same natural graphite composition as in Example was used, and changes in density depending on the particle size of the pitch were compared. The pitch was pulverized, sieved, classified into <75 □m, 75<x<250 μm, and 250<x<500 μm, and hand-mixed. The powder thus mixed was formed under the same conditions at room temperature using a hot-forming machine (Ilshin Autoclave, HT-15T).

TABLE 6

| Pitch size | <75 μm | 75 < x < 250 μm | 250 < x < 500 μm |
|---|---|---|---|
| Density (g cm⁻³) | 1.99 | 1.98 | 1.97 |
| Density after heat | 1.71 | 1.67 | 1.64 |
| treatment (g cm⁻³) | | | |
| Porosity (%) | 18.1 | 19.2 | 20.8 |

As is apparent from Table 6, the forming density did not change significantly depending on the particle size, but after heat treatment, the density increased with a decrease in the particle size. The larger the particle size of the pitch, the larger the porosity. In particular, binder pitch having a size of 100 or more resulted in increased aggregation and porosity and decreased graphite orientation, and hence, it was confirmed that the use of the binder pitch having a size of 75 or less was capable of increasing density and decreasing porosity, ultimately resulting in improved thermal properties.

<Results of Measurement of Thermal Conductivity>

Table 7 below shows the results of measurement of thermal conductivity of each of Test Examples, Comparative Examples, and Example of the present invention.

TABLE 7

| Thermal conductivity | | | Flexural strength |
|---|---|---|---|
| (W/m.K) | In-plane | Through-plane | (MPa) |
| Test Example 1 | 286.9 | 18.0 | 7.42 |
| Test Example 2 | 165.8 | 19.7 | 8.85 |
| Test Example 3 | 23 | 23 | 59 |
| Example | 413.6 | 21.0 | 9.26 |
| Comparative Example 1 | 278.1 | 16.17 | 7.17 |
| Comparative Example 2 | 319.9 | 18.9 | 8.681 |

More specifically, referring to Table 7, it is possible to confirm the following measurement results.

In Test Example 1, thermal conductivity was vastly superior in the x and y axes compared to the z axis.

In Test Example 2, thermal conductivity was relatively low compared to Test Example 1, which is deemed to be due to the effect of boundary scattering between particles.

In Test Example 3, a commercially available block (Nippon coke, GS-203R), which is confirmed to have isotropic properties, was tested for comparison.

In Example, by packing the natural graphite having relatively high thermal conductivity, high thermal conductivity resulted compared to Test Examples 1 and 2. Therefore, through-plane thermal conductivity and strength were improved by controlling the structure of natural graphite compared to Test Examples 1 and 2.

In Comparative Example 1, based on the results of measurement of thermal conductivity of the cold-pressed sample using the composition of Example, thermal conductivity of 67% was exhibited.

In Comparative Example 2, the aggregation of the pitch was low upon cold pressing after reduction in the diameter of the binder pitch, and thus the thermal conductivity was about 77% compared to Example.

As is apparent from the above results, the method of manufacturing the multi-structural high-heat-dissipation part having the controlled packing density of the carbon material according to the present invention is effective at improving the packing density of the carbon material through bimodal distribution using the pieces of carbon material having different diameters, thereby increasing thermal conductivity and strength. Moreover, it is easy to manufacture a multi-structural high-heat-dissipation part having superior thermal conductivity in in-plane and through-plane directions through structural control depending on changes in the diameter of the carbon material.

The method of manufacturing the multi-structural high-heat-dissipation part having the controlled packing density of the carbon material according to the present invention is specified above, and the multi-structural high-heat-dissipation part having the controlled packing density of the carbon material according to the present invention is described below. Here, the configuration of the multi-structural high-heat-dissipation part that is described below is as described above, and thus a detailed description thereof will be omitted.

The multi-structural high-heat-dissipation part according to the present invention is manufactured using the aforementioned method, and may be configured to include a binder pitch and a carbon material.

The carbon material includes a first carbon material powder and a second carbon material powder having a smaller diameter than the diameter of the first carbon material powder, and the binder pitch and the carbon material are mixed, hot-formed and then graphitized, thus producing a pitch/carbon material compact.

Here, the first carbon material powder may have a diameter of 400 to 500 μm, and the second carbon material powder may have a diameter of 10 to 100 μm.

With reference to FIG. 3A, when the carbon material having a large diameter is used alone, it is efficiently arranged in an in-plane direction to which pressure is applied, and thus in-plane thermal conductivity is high, but strength is lowered, which is undesirable. Specifically, when natural graphite having a large diameter is formed using a hot-forming machine, in-plane thermal conductivity is high by virtue of arrangement in the in-plane direction but structural strength is undesirably lowered.

With reference to FIG. 3B, when the carbon material having a relatively small diameter is used alone, it is oriented in random directions, whereby strength is increased, but the binder pitch does not wrap the carbon material having a relatively small diameter, and thus an aggregated binder pitch is created, which is undesirable. Moreover, graphite having a small diameter has superior crystallinity but is nonuniform in thermal conductivity due to the small particle size thereof, and thus, thermal conductivity is decreased compared to relatively large graphite, but the movement path is increased upon measurement of flexural strength due to the structural effect of graphite by virtue of the small particle size, thereby exhibiting higher strength than in the case of large particles.

Accordingly, when the binder pitch is mixed with the carbon material including the first carbon material powder and the second carbon material powder having a smaller diameter than that of the first carbon material powder, as shown in FIG. 2, the second carbon material powder is positioned between particles of the first carbon material powder, thus minimizing voids, thereby improving mechanical and thermal properties.

Under the assumption that the density and thickness of the first carbon material powder and the second carbon material powder are the same and the particles thereof are spherical, the minimum void ratio may be calculated using Equation 1 mentioned above. For example, assuming that the first carbon material powder has a diameter of 500 μm and the second carbon material powder has a diameter of 50 the ratio W_{R}:Wᵣ, at which the voids may be minimized, is calculated to be 78.5:21.5.

Thus, the carbon material may include, based on 100 wt % thereof, 50 to 90 wt % of the first carbon material powder and 10 to 50 wt % of the second carbon material powder, and particularly, about 80 wt % of the first carbon material powder and about 20 wt % of the second carbon material powder.

Meanwhile, the binder pitch may have a particle size of 1 to 100 μm. If the particle size thereof is less than 1 μm, it is difficult to form binder pitch particles. On the other hand, if the particle size thereof exceeds 100 μm, it is difficult to uniformly mix with the carbon material powder.

Here, the graphitized pitch/carbon material compact may have a density of 1.7 to 2.2 g/cm³. Through the above examples, it can be confirmed that the use of the binder pitch and the pieces of carbon material having different diameters is capable of improving the packing density compared to when using the carbon material having the consistent diameter.

Therefore, the multi-structural high-heat-dissipation part having the controlled packing density of the carbon material according to the present invention is effectively improved in packing density and thermal conductivity by manufacturing a heat-dissipation part material using the binder pitch and the pieces of carbon material having different diameters. Through bimodal distribution using the pieces of carbon material having different diameters, the packing density of the carbon material can be improved, thereby effectively increasing thermal conductivity and strength. Moreover, through structural control depending on changes in the diameter of the carbon material, it is easy to manufacture a multi-structural high-heat-dissipation part having superior thermal conductivity in in-plane and through-plane directions.

Although the preferred embodiment of the present invention has been disclosed for illustrative purposes, those skilled in the art will appreciate that various modifications, additions and substitutions are possible without departing from the scope and spirit of the invention as disclosed in the accompanying claims. Thus, the embodiments described above should be understood to be non-limiting and illustrative in every way, and the invention is not limited to the foregoing description but may vary within the scope of the appended claims and their equivalents.

What is claimed is:

1. A method of manufacturing a multi-structural high-heat-dissipation part having a controlled packing density of a carbon material, the method comprising:
preparing a mixture by mixing a binder pitch with a carbon material comprising a first carbon material powder and a second carbon material powder having a smaller diameter than a diameter of the first carbon material powder;
forming a compact from the mixture using a hot-forming process; and
producing a graphitized pitch/carbon material compact by subjecting the compact to graphitization through heat treatment and cooling.

2. The method of claim 1, wherein the first carbon material powder has a diameter of 400 to 500 μm and the second carbon material powder has a diameter of 10 to 100 μm.

3. The method of claim 2, wherein the carbon material comprises 50 to 90 wt % of the first carbon material powder and 10 to 50 wt % of the second carbon material powder based on 100 wt % of the carbon material.

4. The method of claim 1, wherein the carbon material is selected from the group consisting of graphite, carbon black, carbon nanotubes, carbon fiber, graphene and combinations thereof.

5. The method of claim 1, wherein the binder pitch has a softening point of 100° C. to 200° C.

6. The method of claim 1, wherein the binder pitch has a particle size of 1 to 100 μm.

7. The method of claim 1, wherein the mixture includes 10 to 20 wt % of the binder pitch and 80 to 90 wt % of the carbon material based on 100 wt % of the mixture.

8. The method of claim 1, wherein the hot-forming process is performed at a temperature ranging from 200° C. to 400° C.

9. The method of claim 1, wherein the pitch/carbon material compact has a density of 1.7 to 2.2 g/cm³.

10. A multi-structural high-heat-dissipation part having a controlled packing density of a carbon material, the multi-structural high-heat-dissipation part comprising:
a binder pitch; and
a carbon material comprising a first carbon material powder and a second carbon material powder having a smaller size than a size of the first carbon material powder,
wherein the binder pitch and the carbon material are mixed, hot-formed and graphitized, thus producing a pitch/carbon material compact.
